(19) United States
(12) Patent Application Publication
(10) Pub. No.: US 2025/0380492 A1
(43) Pub. Date: Dec. 11, 2025

(54) INTEGRATED PASSIVE DEVICE REGION WITH INCREASED SUBSTRATE THICKNESS

(71) Applicant: International Business Machines Corporation, Armonk, NY (US)

(72) Inventors: Fabio Carta, Pleasantville, NY (US); Tao Li, Slingerlands, NY (US); Ruilong Xie, Niskayuna, NY (US); Robert Gauthier, Williston, VT (US)

(21) Appl. No.: 18/735,977

(22) Filed: Jun. 6, 2024

(51) Int. Cl. H01L 27/06; H01L 23/528; H01L 29/06; H01L 29/40; H01L 29/417; H01L 29/423; H01L 29/66; H01L 29/775; H01L 29/786

(52) U.S. Cl. CPC H10D 84/811; H01L 23/5286; H10D 30/014; H10D 30/031; H10D 30/43; H10D 30/6729; H10D 30/6735; H10D 30/6757; H10D 62/121; H10D 64/01

(57) ABSTRACT

A semiconductor integrated circuit device includes a passive device region and one or more logic region(s). The passive device region includes a semiconductor substrate region (e.g. a retained substrate structure) below a doped semiconductor region. The passive device region further includes a crystalline semiconductor material layer directly coupled with a backside of the semiconductor substrate region. The logic region(s) includes a front end of line (FEOL) transistor with a first source/drain region and a second source/drain region, and a backside contact directly coupled with the first source/drain region. A frontside surface of the crystalline semiconductor material layer is substantially coplanar with a backside surface of the backside contact. Due to the crystalline semiconductor material layer, the semiconductor material within the passive device region is relatively increased which may improve functionality of passive device(s), such as such as resistors, capacitors, inductors, transformers, diodes, that may be formed therein.

### BACKGROUND

Modern semiconductor integrated circuit (IC) devices include various types of microdevices, such as transistors and passive devices, such as resistors, capacitors, inductors, transformers, and even diodes. Embodiments of the present disclosure provide for the integration and/or fabrication of such transistors and one or more passive devices utilizing the same or similar advanced technology fabrication stages, such as nanosheet gate all around (GAA) transistor fabrication stages, or the like.

### SUMMARY

In an embodiment of the disclosure, a semiconductor integrated circuit (IC) device is presented. The semiconductor IC device includes a passive device region that includes a semiconductor substrate region below a doped semiconductor region and a crystalline semiconductor material layer directly coupled with a backside of the semiconductor substrate region. The semiconductor IC device further includes a logic region that includes a front end of line (FEOL) transistor with a first source/drain region and a second source/drain region, and a backside contact directly coupled with the first source/drain region. The frontside surface of the crystalline semiconductor material layer is substantially coplanar with a backside surface of the backside contact.

In an embodiment of the disclosure, another semiconductor IC device is presented. The semiconductor IC device includes a semiconductor substrate. The semiconductor IC device includes a doped semiconductor region upon a frontside of the semiconductor substrate. The semiconductor IC device includes a crystalline semiconductor material layer upon a backside of the semiconductor substrate. The semiconductor IC device further includes a front end of line (FEOL) transistor with a first source/drain region and a second source/drain region, and a backside contact directly coupled with the first source/drain region. A frontside surface of the crystalline semiconductor material layer is substantially coplanar with a backside surface of the backside contact.

In another embodiment of the present disclosure, a semiconductor IC device fabrication method is presented. The method includes forming a transistor upon a semiconductor substrate. The method further includes, within a logic region, removing the semiconductor substrate, and within a passive device region, maintaining the semiconductor substrate. The method further includes forming a backside contact in direct contact with a source/drain region of the transistor. The method further includes forming an amorphous semiconductor material layer upon the semiconductor substrate and upon the backside contact and laser annealing the amorphous semiconductor material layer to form a crystalline semiconductor material layer.

In another embodiment of the present disclosure, another semiconductor IC device is presented. The semiconductor IC device includes a passive device region that includes a semiconductor substrate structure and a crystalline semiconductor material layer upon a backside of the semiconductor substrate structure. The semiconductor IC device further includes a logic region that includes a first backside interlayer dielectric (ILD). A backside of the first ILD is coplanar with the backside of the semiconductor substrate structure. The semiconductor IC device further includes a second backside ILD upon a backside of the first backside ILD and upon the backside of the crystalline semiconductor material layer.

In another embodiment of the present disclosure, another semiconductor IC device is presented. The semiconductor IC device includes a passive device region that includes a semiconductor substrate structure and a crystalline semiconductor material layer upon a backside of the semiconductor substrate structure. The semiconductor IC device further includes a logic region that includes a backside planar transistor comprising a backside transistor channel and backside transistor source/drain regions. Respective backside surfaces of the backside transistor channel and the backside transistor source/drain regions are coplanar with a backside surface of the crystalline semiconductor material layer.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-section view of a semiconductor IC device that includes a passive device region with an increased substrate thickness integrated with a logic region that includes one or more transistors, according to one or more embodiments of the disclosure.

FIG. 2 depicts partial structure top-down view of a semiconductor IC device includes a passive device region with an increased substrate thickness integrated with a logic region that includes one or more transistors, according to one or more embodiments of the disclosure.

FIG. 3 through FIG. 12 depict various fabrication structure cross-section views of an illustrative semiconductor IC device that includes a passive device region with an increased substrate thickness integrated with a logic region that includes one or more transistors, according to one or more embodiments of the disclosure.

FIG. 13 depicts a method of fabricating a semiconductor IC device that includes a transistor and a vertical diode, according to one or more embodiments of the disclosure.

### DETAILED DESCRIPTION

The embodiments of the present disclosure relate to fabrication methods and resulting structures for semiconductor devices. More specifically, the present disclosure relates to fabrication methods and resulting semiconductor IC devices that include a passive device region with an increased substrate thickness integrated with a logic region that includes one or more transistors. Typically, during backside processing of the semiconductor IC device, the substrate structure is removed. However, according to embodiments of the disclosure, within the passive device region, not only is the substrate structure retained a semiconductor material layer is deposited so as to improve functionality of one or more passive devices, such as such as resistors, capacitors, inductors, transformers, diodes, therein. Within the logic region, a residual portion of the semiconductor material layer may be retained and utilized in forming a backside transistor or other microdevice.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating a semiconductor IC device, such as a processor, field programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain regions and uses electrons as the charge carrier. The pFET includes p-doped source and drain regions and uses holes as the charge carrier. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths.

For some semiconductor IC devices, integration of transistors and diodes with a backside back-end-of-line (BEOL) network is one of the key challenges to providing increasing packaged IC device densities and performance increases. By incorporating a backside BEOL network into the semiconductor IC device, routing congestion may be eased. Currently, there is a need for semiconductor IC device fabrication techniques that integrate transistors and diodes with a backside BEOL network.

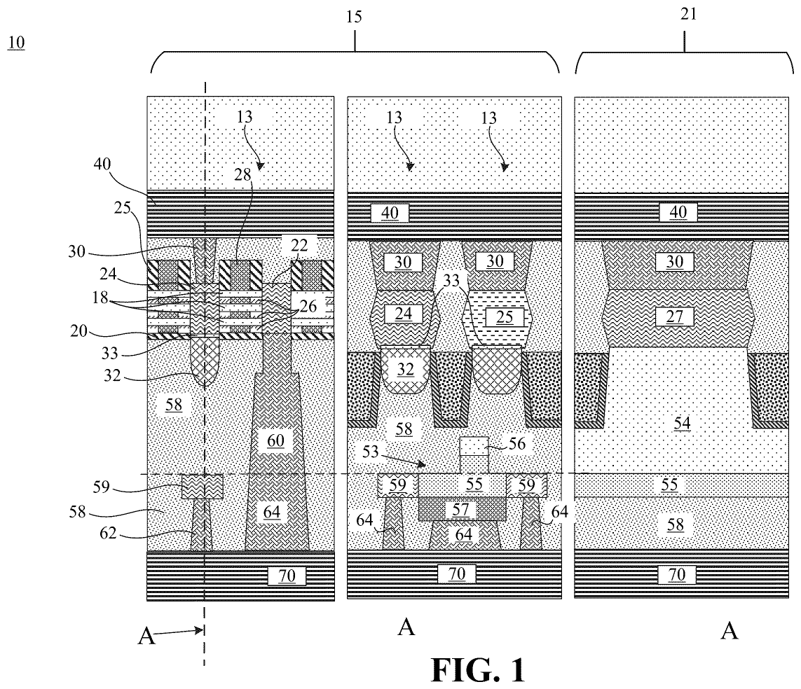

FIG. 1 depicts a cross-section view of a semiconductor IC device 10 that includes a passive device region 21 with an increased substrate thickness integrated with a logic region 15, or logic region, that includes one or more transistors 13, according to one or more embodiments of the disclosure. FIG. 1 depicts an initial cross-sectional view across gate structures 28 in the logic region 15, cross-section A between gate structures 28 that is perpendicular to the initial cross-section in the logic region 15, and a cross-section that is parallel to cross-section A in a passive device region 21.

In an example, the logic region 15 may include one or more transistors 13 that may include a first source/drain region 22, a second source/drain region 24, one or more channels 18 between the first source/drain region 22 and the second source/drain region 24, and a gate structure 28 around the one or more channels 18. A bottom isolation region 20 may be between the gate structure 28 and a backside interlayer dielectric (ILD) 58. A gate spacer 25 may be around a respective gate structure 28. A respective inner spacer 26 may be located above or below a respective channel 18 and may at least partially electrically isolate the gate structure 28 from the first source/drain region 22 or the second source/drain region 24. For clarity, a horizontal dashed line is depicted and may be a boundary between different backside ILD layers and/or depositions.

In an example, the first source/drain region 22 may be in contact with a backside contact 60 which may be electrically connected to respective one or more wires within a backside BEOL network 70 by a backside via 64. The second source/drain region 24 may be in contact with a frontside contact 30 which may be electrically connected to one or more wires within frontside BEOL network 40 by a frontside via (not shown). A backside contact placeholder 32 may be below the second source/drain region 24. In the depicted example, a barrier layer 33 may be between the backside contact placeholder 32 and the second source/drain region 24.

In an example, different transistors 13 in the logic region 15 may include different type source/drain regions. For example, the second source/drain region 24 in a first transistor 13 may be a n-type or p-type source/drain region and an adjacent source/drain region 24 in a backside transistor 13 may be the relatively different type of source/drain region. A shallow trench isolation (STI) region 27 may be located between and/or adequately electrically separate the first transistor 13 from the backside transistor 13.

In an example, the passive device region 21 includes a semiconductor substrate region 54, which may be a monocrystalline semiconductor material, that is below a doped semiconductor region 27. The doped semiconductor region 27 may be simultaneously formed with one or more of the source/drain regions in the logic region 15. The doped semiconductor region 27 may be in contact with a frontside contact 30 which may be electrically connected to one or more wires within the frontside BEOL network 40 by a frontside via (not shown). A crystalline semiconductor material layer 55 may be located on the backside of the semiconductor substrate region 54. As such, the semiconductor material thickness within the passive device region 21, between the doped semiconductor region 27 and the backside BEOL network 70, is relatively larger due to the presence of the crystalline semiconductor material layer 55, which may be beneficial to the various passive device, such as resistors, capacitors, inductors, transformers, diodes, therein.

In an example, within the logic region 15 a residual portion of the crystalline semiconductor material layer 55 may be utilized for form a microdevice upon the backside ILD, such as a passive device, or a logic device, such as a backside transistor 53. For example, the residual portion of the crystalline semiconductor material layer 55 may be utilized as a channel between backside source/drain regions 59. A backside gate 57 may be used to control the flow of carriers through the residual portion of the crystalline semiconductor material layer 55 between the backside source/drain regions 59. The backside source/drain regions 59, the backside gate 57, and the backside contact 60 may be electrically connected to a backside BEOL network 70 by a respective backside interconnect, such as a via 64.

In an embodiment of the present disclosure, a first instance of semiconductor IC device 10 is presented. This semiconductor IC device 10 includes the passive device region 21 that includes the semiconductor substrate region 54 located below the doped semiconductor region 27 and the crystalline semiconductor material layer 55 directly coupled with a backside of the semiconductor substrate region 54. This semiconductor IC device 10 further includes the logic region 15 that includes the front end of line (FEOL) transistor (i.e., transistor 13) with the first source/drain region 22 and the second source/drain region 24, and the backside contact 60 directly coupled with the first source/drain region 22. The frontside surface of the crystalline semiconductor material layer 55 is substantially coplanar with a backside surface of the backside contact 60.

The frontside surface of the crystalline semiconductor material layer 55 being substantially coplanar with the backside surface of the backside contact 60 may result due to an associated semiconductor material layer (e.g., an amorphous semiconductor material layer) being deposited upon the semiconductor substrate region 54 within the passive device region 21 and upon the backside ILD 58 within the logic region 15. Due to the crystalline semiconductor material layer 55, the semiconductor material between the doped semiconductor region 27 and the backside BEOL network 70 within the passive device region 21 is relatively increased which may improve functionality of one or more passive devices (not shown), such as such as resistors, capacitors, inductors, transformers, diodes, therewithin.

In an example, the logic region 15 further includes the backside ILD 58 around the backside contact 60. The backside surface of the backside ILD 58 and the backside contact 60 may be relatively coplanar and the associated semiconductor material layer (e.g., the amorphous semiconductor material layer) may further be deposited upon the backside contact 60.

In an example, the logic region 15 further includes the backside transistor 53 that includes a channel composed of a residual portion of the crystalline semiconductor material layer 55. The crystalline semiconductor material layer 55 that which may be formed on the backside of the backside ILD 58, the backside contact 60, and the semiconductor substrate region 54 may be patterned within the logic region 15 and retained or maintained in the passive device region 21. After the patterning, a retained portion of the crystalline semiconductor material layer 55 within the logic region 15 may be utilized as the channel of the backside transistor 53.

In an example, the residual portion of the crystalline semiconductor material layer 55 includes an upper section above the backside of the semiconductor substrate region 54 and a lower section below the backside of the semiconductor substrate region 54. For example, the channel of the backside transistor 53 may have an upside down “T” shape with a vertical portion that extends above the backside of the semiconductor substrate region 54 and a horizontal portion that is below the backside of the semiconductor substrate region 54.

In an example, the logic region 15 further includes an amorphous semiconductor region 56 directly coupled to a frontside surface of the upper section of the residual portion of the crystalline semiconductor material layer 55. The amorphous semiconductor region 56 may be the residual portion of the amorphous semiconductor material layer that did not crystalize during the anneal thereof that forms the crystalline semiconductor material layer 55.

In an example, the backside transistor 53 further includes the first backside source/drain region 59 directly coupled to a first sidewall of the residual portion of the crystalline semiconductor material layer 55 and a second backside source/drain region 59 directly coupled to a second sidewall of the residual portion of the crystalline semiconductor material layer 55. For example, the backside transistor 53 may be a planar transistor.

In an example, the backside transistor 53 further includes the backside gate 57 directly coupled to a backside surface of the residual portion of the crystalline semiconductor material layer 55. In this manner, the backside gate 57 may have a potential that is controlled or dictated from the backside of the semiconductor IC device 10.

In an example, the backside contact 60, the first backside source/drain region 59, the second backside source/drain region 59, and the backside gate 57 are electrically connected to the backside BEOL network 70. As such, signal and/or power routing to the backside contact 60, the first backside source/drain region 59, the second backside source/drain region 59, and the backside gate 57 may be provided by the backside BEOL network 70.

In an example, the second source/drain region 24 and the doped semiconductor region 27 are electrically connected to the frontside BEOL network 40. In this way, signal and/or power routing may be sufficiently split between the frontside BEOL network 40 and the backside BEOL network 70 and resulting associated semiconductor IC device 10 efficiencies may be gained.

In an embodiment of the present disclosure, a second instance of semiconductor IC device 10 is presented. This semiconductor IC device 10 includes a semiconductor substrate (i.e., semiconductor substrate region 54), the doped semiconductor region 27 upon a frontside of the semiconductor substrate. This semiconductor IC device 10 further includes the crystalline semiconductor material layer 55 upon a backside of the semiconductor substrate. This semiconductor IC device 10 further includes the front end of line (FEOL) transistor 13 that includes the first source/drain region 22 and the second source/drain region 24 and the backside contact 60 directly coupled with the first source/drain region 22. A frontside surface of the crystalline semiconductor material layer 55 is substantially coplanar with a backside surface of the backside contact 60.

The frontside surface of the crystalline semiconductor material layer 55 being substantially coplanar with the backside surface of the backside contact 60 may result due to an associated semiconductor material layer (e.g., an amorphous semiconductor material layer) being deposited upon the semiconductor substrate region 54 within the passive device region 21 and upon the backside ILD 58 within the logic region 15. Due to the crystalline semiconductor material layer 55, the semiconductor material between the doped semiconductor region 27 and the backside BEOL network 70 within the passive device region 21 is relatively increased which may improve functionality of one or more passive devices (not shown), such as such as resistors, capacitors, inductors, transformers, diodes, therewithin.

In an example, this semiconductor IC device 10 further includes the backside ILD 58 around the backside contact. The backside surface of the backside ILD 58 and the backside contact 60 may be relatively coplanar and the associated semiconductor material layer (e.g., the amorphous semiconductor material layer) may further be deposited upon the backside contact 60.

In an example, this semiconductor IC device 10 further includes the backside transistor 53 that includes a channel that is formed by a residual portion of the crystalline semiconductor material layer 55. The crystalline semiconductor material layer 55 that which may be formed on the backside of the backside ILD 58, the backside contact 60, and the semiconductor substrate region 54 may be patterned within the logic region 15 and retained or maintained in the passive device region 21. After the patterning, a retained portion of the crystalline semiconductor material layer 55 within the logic region 15 may be utilized as the channel of the backside transistor 53.

In an example, the residual portion of the crystalline semiconductor material layer 55 includes an upper section above the backside of the semiconductor substrate and a lower section below the backside of the semiconductor substrate. For example, the channel of the backside transistor 53 may have an upside down “T” shape with a vertical portion at least partially above the backside of the semiconductor substrate region 54 and a horizontal portion at least partially below the backside of the semiconductor substrate region 54.

In an example, this semiconductor IC device 10 further includes the amorphous semiconductor region 56 directly coupled to a frontside surface of the upper section of the residual portion of the crystalline semiconductor material layer 55. The amorphous semiconductor region 56 may be the residual portion of the amorphous semiconductor material layer that did not crystalize during the anneal thereof that forms the crystalline semiconductor material layer 55.

In an example, the backside transistor 53 further comprises the first backside source/drain region 59 directly coupled to a first sidewall of the residual portion of the crystalline semiconductor material layer 55 and the second backside source/drain region 59 directly coupled to a second sidewall of the residual portion of the crystalline semiconductor material layer 55. For example, the backside transistor 53 may be a planar transistor.

In an example, the backside transistor 53 further includes a backside gate 57 directly coupled to a backside surface of the residual portion of the crystalline semiconductor material layer 55. In this manner, the backside gate 57 may have a potential that is controlled or dictated from the backside of the semiconductor IC device 10.

In an example, this semiconductor IC device 10 further includes the backside BEOL network 70 and wherein the backside contact 60, the first backside source/drain region 59, the second backside source/drain region 59, and the backside gate 57 are electrically connected to the backside BEOL network 70. As such, signal and/or power routing to the backside contact 60, the first backside source/drain region 59, the second backside source/drain region 59, and the backside gate 57 may be provided by the backside BEOL network 70.

In an example, this semiconductor IC device 10 further includes a frontside BEOL network 40 and the second source/drain region 24 and the doped semiconductor region 27 are electrically connected to the frontside BEOL network 40. In this way, signal and/or power routing may be sufficiently split between the frontside BEOL network 40 and the backside BEOL network 70 and resulting associated semiconductor IC device 10 efficiencies may be gained.

In another embodiment of the present disclosure, an illustrative semiconductor integrated circuit (IC) device 10 fabrication method is presented. The method includes forming the transistor 13 upon a semiconductor substrate. The method further includes, within the logic region 15, removing the semiconductor substrate, and within the passive device region 21, maintaining the semiconductor substrate to form the semiconductor substrate region 54. The method further includes forming the backside contact 60 in direct contact with the first source/drain region 22 of the transistor 13. The method further includes forming an amorphous semiconductor material layer upon a backside of the semiconductor IC device 10. The method further includes laser annealing the amorphous semiconductor material layer to form a crystalline semiconductor material layer 55.

Due to the crystalline semiconductor material layer 55, the semiconductor material between the doped semiconductor region 27 and the backside BEOL network 70 within the passive device region 21 is relatively increased which may improve functionality of one or more passive devices (not shown), such as such as resistors, capacitors, inductors, transformers, diodes, therewithin. Further, laser annealing may adequately anneal the amorphous semiconductor material layer while limiting the exposure or subjection other regions of the semiconductor IC device 10 (e.g., source/drain regions 22, 24) to temperature that which causes material property or structure degradation, or the like.

In an example, the method further includes maintaining the crystalline semiconductor material layer in the passive device region 21 and patterning the crystalline semiconductor material layer in the logic region 15. Due to the crystalline semiconductor material layer 55, the semiconductor material between the doped semiconductor region 27 and the backside BEOL network 70 within the passive device region 21 is relatively increased which may improve functionality of one or more passive devices therewithin.

In an example, the patterning the crystalline semiconductor material layer in the logic region 15 forms a backside transistor channel of a backside transistor 53 that is composed of a residual portion of the crystalline semiconductor material layer 55. For instance, rather than removing the crystalline semiconductor material layer 55 in the logic region, respective portions thereof may be maintained and utilized in the creation of other devices, such as a backside transistor 53.

In an example, the method further includes forming the first backside source/drain region 59 against a first sidewall of the residual portion of the crystalline semiconductor material layer 55 and forming a second backside source/drain region 59 against a second sidewall of the residual portion of the crystalline semiconductor material layer 55. For example, the backside transistor 53 may be a planar transistor.

In an example, the method further includes forming a backside gate 57 against a backside surface of the residual portion of the crystalline semiconductor material layer 55. In this manner, the backside gate 57 may have a potential that is controlled or dictated from the backside of the semiconductor IC device 10.

In an example, the method further includes forming the BEOL network 70 that is electrically connected to the backside contact 60, to the first backside source/drain region 59, to the second backside source/drain region 59, and to the backside gate 75. As such, signal and/or power routing to the backside contact 60, the first backside source/drain region 59, the second backside source/drain region 59, and the backside gate 57 may be provided by the backside BEOL network 70.

In an example, a frontside surface of the crystalline semiconductor material layer 55 is substantially coplanar with a backside surface of the backside contact 60. The frontside surface of the crystalline semiconductor material layer 55 being substantially coplanar with the backside surface of the backside contact 60 may result due to an associated semiconductor material layer (e.g., an amorphous semiconductor material layer) being deposited upon the semiconductor substrate region 54 within the passive device region 21 and upon the backside ILD 58 within the logic region 15. Due to the crystalline semiconductor material layer 55, the semiconductor material between the doped semiconductor region 27 and the backside BEOL network 70 within the passive device region 21 is relatively increased which may improve functionality of one or more passive devices (not shown), such as such as resistors, capacitors, inductors, transformers, diodes, therewithin.

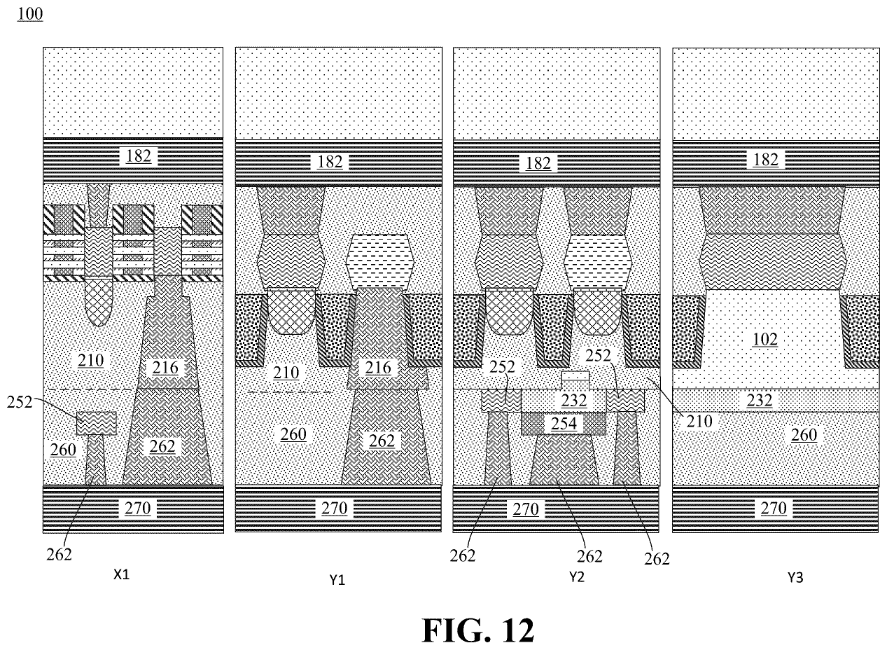

In another embodiment of the present disclosure, another instance of semiconductor IC device 10 is presented. The semiconductor IC device 10 includes the passive device region that includes the semiconductor substrate structure (e.g., upper substrate 102 as depicted in FIG. 12) and the crystalline semiconductor material layer 55 upon the backside of the semiconductor substrate structure. The semiconductor IC device 10 further includes the logic region that includes the first backside ILD (e.g., backside ILD 210 as depicted in FIG. 12). A backside of the first backside ILD is coplanar with the backside of the semiconductor substrate structure. The semiconductor IC device 10 further includes a second backside ILD (e.g., backside ILD 260 as depicted in FIG. 12) upon a backside of the first backside ILD and upon the backside of the crystalline semiconductor material layer 55.

Due to the crystalline semiconductor material layer 55 in the passive device region, the semiconductor material within the passive device region 21 is relatively increased which may improve functionality of one or more passive devices (not shown), such as such as resistors, capacitors, inductors, transformers, diodes, therewithin. Further, residual crystalline semiconductor material layer 55 may be retained within the logic region(s) and may be utilized as e.g., the channel for the backside transistor, which may increase overall semiconductor IC device 10 performance.

In another embodiment of the present disclosure, another instance of semiconductor IC device 10 is presented. The semiconductor IC device 10 includes a passive device region that includes a semiconductor substrate structure (e.g., upper substrate 102 as depicted in FIG. 12) and the crystalline semiconductor material layer 55 upon a backside of the semiconductor substrate structure. The semiconductor IC device 10 further includes a logic region with a backside planar transistor comprising a backside transistor channel (e.g., residual crystalline semiconductor material layer 55) and backside transistor source/drain regions 59. Respective backside surfaces of the backside transistor channel and the backside transistor source/drain regions 59 are coplanar with a backside surface of the crystalline semiconductor material layer 55.

Due to the crystalline semiconductor material layer 55 in the passive device region, the semiconductor material within the passive device region 21 is relatively increased which may improve functionality of one or more passive devices (not shown), such as such as resistors, capacitors, inductors, transformers, diodes, therewithin. Further, residual crystalline semiconductor material layer 55 may be retained within the logic region(s) and may be utilized as e.g., the channel for the backside transistor, which may increase overall semiconductor IC device 10 performance.

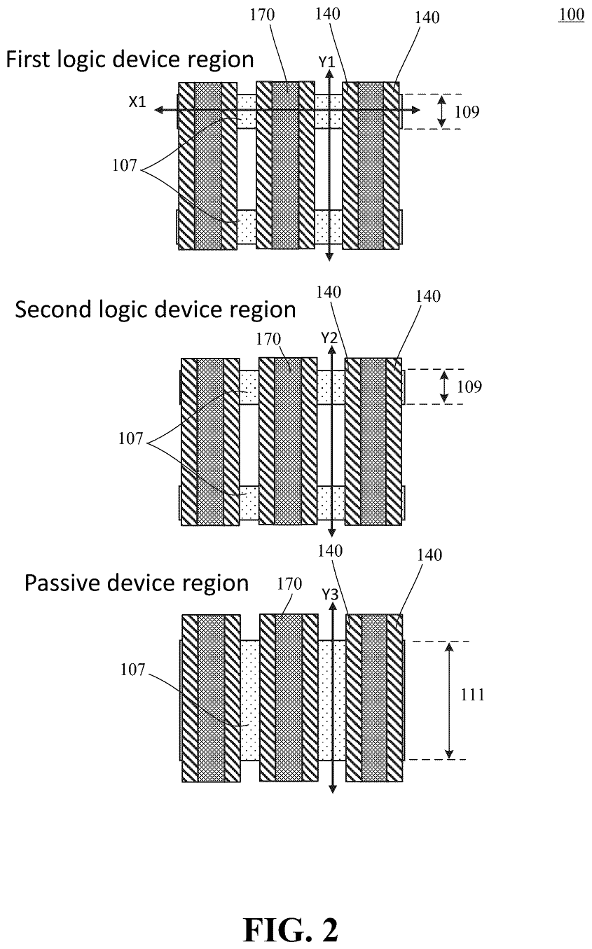

FIG. 2 depicts a partial structural top-down view of a semiconductor IC device 100 that includes a first logic region, a second logic region, and a passive device region. A cross-sectional plane X1, which is a vertical plane in the first logic region, is located across replacement gate structures 170 along a nanolayer row 107 and a cross-sectional plane Y1, which is a vertical plane in the first logic region, is located across nanolayer rows 107 and is between replacement gate structures 170. A cross-sectional plane Y2, which is a vertical plane in the second logic region, is located across nanolayer rows 107 and is between replacement gate structures 170. A cross-sectional plane Y3, which is a vertical plane in the first logic region, is located across a nanolayer row 107 and is between replacement gate structures 170.

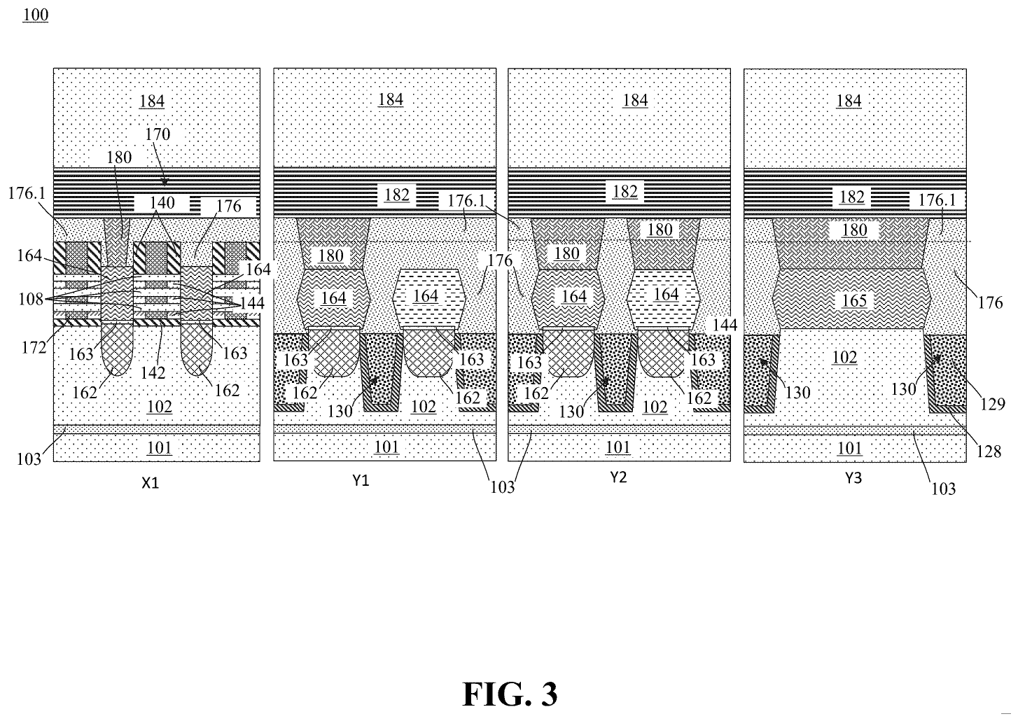

Also depicted in FIG. 2 are respective gate spacer(s) 140 around respective replacement gate structures 170. For clarity, the active nanolayers 108 depicted, for example, in FIG. 3, are formed by processing nanolayer rows 107 that are vertically stacked into and/or out of the page of FIG. 2. For clarity, a dimension 109 of the nanolayer rows 107 within the logic regions may be larger than an associated dimension 111 of the nanolayer row within the passive device region. Such dimensions 109, 111 may set or be otherwise associated with a horizontal dimension of the upper substrate 102 between STI regions 130, as depicted in FIG. 3.

FIG. 3 depicts an initial fabrication structure cross-section view of an illustrative semiconductor IC device 100 that includes a passive device region with an increased substrate thickness integrated with a logic region that includes one or more transistors, according to one or more embodiments of the disclosure. At this initial fabrication stage, the semiconductor IC device 100 may include a lower substrate 101, an etch stop layer 103, an upper substrate 102, STI regions 130, backside contact placeholders 162, separation layers 163, bottom isolation 142, source/drain (S/D) regions 164, faux S/D regions 165, replacement gate structures 170, gate spacers 140, active semiconductor nanolayers 108, inner spacers 144, a frontside ILD 176, a frontside contact ILD 176.1, frontside contacts 180, a frontside BEOL network 182, and a carrier wafer 184, etc. For clarity, faux S/D regions 165 and one or more of the S/D regions 164 may be composed of a substantially similar, the same, material at a same or similar fabrication stage. However, faux S/D regions 165 may be referred to herein as faux due to an absence of a respective channel and gate associated with the faux S/D regions 165.

For clarity, various background fabrication stages are described below that may be used to form the depicted semiconductor IC device 100. These background fabrication stages may reference structures that are not shown in the present cross-sections, but descriptions of the formation thereof are included herein to better describe the initial fabrication structure of the semiconductor IC device 100.

The illustrative semiconductor IC device 100 may be formed by initially providing or forming a substrate structure. The substrate structure may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, crystalline silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors.

In the depicted implementation, the substrate structure includes an upper substrate 102, a lower substrate 101, and an etch stop layer 103 between the upper substrate 102 and the lower substrate 101. The upper substrate 102 and the lower substrate 101 may be comprised of any suitable material(s) including those listed above, and may illustratively be a crystalline semiconductor material, and the etch stop layer 103 may be a dielectric material with etch selectivity to one or both of the upper substrate 102 and/or the lower substrate 101. In one example, the etch stop layer 103 may be an oxide and the substrate structure may be referred to as a buried oxide (BOX) substrate. In another example, the lower substrate 101 may be composed of Si. The etch stop layer 103 may be composed of Silicon Germanium (SiGe) and may be epitaxially grown from the top surface of lower substrate 101 and the upper substrate 102 may be composed of Si and may be epitaxially grown from the top surface of etch stop layer 103.

Next, the illustrative semiconductor IC device 100 may be formed by forming nanolayers over the substrate structure by forming a bottommost sacrificial nanolayer (not shown) and by forming a series of alternating sacrificial nanolayers (not shown) and active nanolayers 108, thereupon.

The nanolayers may be further formed by fabricating the alternating series of sacrificial nanolayers, such as SiGe sacrificial nanolayers, and active nanolayers 108, such as Si nanolayers, upon the bottommost sacrificial nanolayer. The sacrificial nanolayers can have Ge percentages ranging from 20% to 45%. In an implementation, the alternating active sacrificial nanolayer and active nanolayer 108 may be formed by epitaxially growing each layer until the desired number and desired thicknesses of the layers are achieved. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Further, in the depicted fabrication stages, the nanolayers may be patterned into nanolayer stacks and shallow trench isolation (STI) regions 130 may be formed within the substrate structure adjacent to the nanolayer stacks.

To form one or more nanolayer rows, lithography and etch process may be utilized. Following the nanolayer row patterning process, the one or more nanolayer rows are formed and one or more STI region openings may be formed. A STI region 130 may be formed upon and/or within the substrate structure within respective STI region openings. The STI regions 130 may be formed by depositing electrical dielectric material(s) within respective STI region opening(s) that are adjacent to the one or more nanolayer stacks. A top surface of the one or more STI regions 130 may be initially coplanar with or below a top surface of the substrate structure. In some implementations, further fabrication operations may generally remove portions of the STI regions 130 (e.g., sacrificial gate removal, replacement gate fabrication pre-clean, etc.), such that the top surfaces of the STI regions 130 are below the top surface of the substrate structure. The one or more STI regions 130 may have a volume and/or geometry that sufficiently electrically isolates components or features of neighboring transistors.

In an example, the STI region(s) 130 may be formed by depositing a STI liner 128 within the STI region openings. Subsequently, STI region(s) 130 may be further formed by depositing STI dielectric material 129 upon the STI liner 128. A etch back, recess, or the like, may occur to remove undesired or over formed STI liner and/or STI dielectric material, such that the top surface of the STI region(s) 130 are coplanar with or below a bottom surface of the bottommost sacrificial nanolayer. STI liner 128 may be composed of but not limited to a nitride, low-κ nitride (i.e., a nitride material with a lower dielectric constant relative to SiO₂), or the like. The STI dielectric material 129 may be composed of but not limited to an oxide, low-κ oxide (i.e., an oxide material with a lower dielectric constant relative to SiO₂), or the like.

The illustrated semiconductor IC device 100 may be further fabricated by next forming sacrificial gate structures (not shown). The sacrificial gate structures may include a sacrificial gate liner, a sacrificial gate, and a sacrificial gate cap. The sacrificial gate structures may be formed by initially depositing a sacrificial gate liner layer (e.g., a dielectric, oxide, or the like) upon the one or more STI regions 130 and upon and around the one or more nanolayer stacks. The sacrificial gate structures may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer stacks. The sacrificial gate structures may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner, the sacrificial gate, and the sacrificial gate cap, respectively, of each of the one or more sacrificial gate structures.

The illustrated semiconductor IC device 100 may be further fabricated by next removing the bottommost sacrificial nanolayer and by forming gate spacers 140 and a bottom isolation 142 in place of the removed bottommost sacrificial nanolayer within the nanolayer stacks. The gate spacer(s) 140 may be formed upon the sidewall(s) of the sacrificial gate structures, upon the STI region(s) 130, and around the one or more nanolayer stacks.

The bottom isolation 142 and the gate spacer(s) 140 may be simultaneously formed by a conformal deposition of a dielectric material, such as silicon nitride, SiBCN, SiNC, SiN, SiCO, SiNOC, or a combination thereof, or the like, within the nanolayer cavity(ies), upon STI regions 130, upon around the one or more sacrificial gate structures, and upon and around the one or more nanolayer stack(s). Subsequently, undesired portions of dielectric material may be removed while desired portions the dielectric material may be retained and thereby form the bottom isolation 142 and the gate spacer(s) 140. The undesired portions of dielectric material may be removed by a directional ion etch, such as a reactive ion etch (RIE). The RIE may remove exposed or unprotected horizontal portions of the dielectric material while retaining protected horizontal portions of the dielectric layer (e.g., the bottom isolation 142) and vertical portions of the dielectric layer (e.g., the gate spacer(s) 140).

The illustrated semiconductor IC device 100 may be further fabricated by next forming recesses within the one or more nanolayer rows between gate spacers 140 of neighboring sacrificial gate structures. In other words, a single nanolayer row may be separated, by one or more recesses, into multiple nanolayer stacks each located underneath at a portion of respective sacrificial gate structure and associated gate spacers 140.

The undesired portions of sacrificial nanolayers, active nanolayers 108, and the like, may be removed by etching or other subtractive removal techniques. The top surface of the substrate structure may be used as an etch stop or other etch parameters may be controlled to stop the material removal at the substrate structure. As the gate spacers 140 and the sacrificial gate structures may be utilized to protect the underlying portions of sacrificial nanolayers, active nanolayers 108, and bottom isolation 142 (if present), respective sidewalls of the nanolayer stacks may be substantially coplanar and substantially vertical with the outer sidewalls of the gate spacers 140 there above.

As used herein, “substantially vertical” sidewalls deviate from a direction normal to a major surface (e.g., top surface, etc.) of the substrate 102 by less than 5°, e.g., 0°, 1°, 2°, 3°, 4°, or 5°, including ranges between any of the foregoing values.

The illustrated semiconductor IC device 100 may be further fabricated by next forming horizontal or lateral indents by laterally or horizontally removing respective portions of sacrificial nanolayers within the nanolayer stacks. The indents may be formed by a reactive ion etch (RIE) process, which can remove portions of the sacrificial nanolayers. The horizontal depth of the indents may be chosen to set a length for a replacement gate structure 170, that is formed in place of one sacrificial gate structure. When the sacrificial nanolayers are composed of SiGe and when active nanolayers 108 are Si, the directional RIE can use a boron-based chemistry or a chlorine-based chemistry, for example, which recesses or removes the exposed end portions of sacrificial nanolayers (e.g., end portions of sacrificial nanolayers generally below spacer 140) selective to the Si active nanolayers 108. In alternative implementations when sacrificial nanolayers are not SiGe and when active nanolayers 108 are not Si, the directional etch of the sacrificial nanolayers may generally be selective to the active nanolayers 108, gate spacers 140, STI regions 130, and/or substrate structure.

The illustrated semiconductor IC device 100 may be further fabricated by next forming a respective inner spacer 144 within each indent. The one or more inner spacers 144 can be formed by ALD or CVD or any other suitable deposition technique that deposits a dielectric material within the indent(s), thereby forming the inner spacer(s). In some examples, the inner spacer(s) 144 are composed of a low-κ dielectric material (a material with a lower dielectric constant relative to SiO₂), SiN, SiO, SiBCN, SiOCN, SiCO, etc. or any other suitable dielectric material. In certain implementations, after the formation of the inner spacer(s) 144, an isotropic etch process is performed to create substantially vertical sidewalls of the inner spacer(s) 144 that are coplanar with the substantially vertical sidewalls of the active nanolayers 108, of the gate spacers 140, and/or of the bottom isolation 142.

The illustrated semiconductor IC device 100 may be further fabricated by next forming one or more backside contact placeholders 162 within the substrate structure within the logic regions in between adjacent sacrificial gate structures within a respective recess. In one example, a respective backside contact placeholder 162 may be formed in all recess location(s) within the logic regions such that a respective backside contact placeholder 162 is located underneath each S/D region 164 therein.

The one or more backside contact placeholders 162 may be formed by epitaxially growing an epitaxial material from exposed substrate structure surface(s) within the one or more backside contact placeholder(s) cavities. In some embodiments, epitaxial growth and/or deposition processes may be selective to forming on the semiconductor surfaces of the upper substrate 102, and may not deposit material on dielectric surfaces, such as silicon dioxide or silicon nitride surfaces. In some embodiments, the epitaxial growth of the one or more backside contact placeholders 162 may overgrow above the top surface of the substrate structure or above the top surface of bottom isolation 142. In an example, the epitaxial material of the one or more backside contact placeholders 162 may be chosen to be etch selective to the material of the S/D region(s) 164, the material of the upper substrate 102, or the like.

In another example, a separation layer 163 (e.g., a Si epitaxially grown layer, or the like) may be formed upon the top surface of the backside contact placeholders 162. For example, the one or more backside contact placeholders 162 may be SiGe and a Si separation layer 163 may be epitaxially grown from the top surface of the SiGe backside contact placeholders 162. Respective top surfaces of the backside contact placeholders 162 (or separation layer 163 thereupon) may be substantially horizontal and below the bottom surface of the bottommost active nanolayer 108 (e.g., to enable contact between such active nanolayer 108 and the S/D region 164) and/or substantially coplanar with a respective one or more top surface(s) of bottom isolation 142.

The illustrated semiconductor IC device 100 may be further fabricated by next forming one or more respective S/D regions 164 upon a respective backside contact placeholder 162 within the logic regions and by forming one or more faux S/D regions 165 in the passive device region. For example, p-doped S/D regions 164 and/or p-doped faux S/D regions 165 may be simultaneously formed in a first formation sequence and then n-doped S/D regions 164 and/or n-doped faux S/D regions 165 may be simultaneously formed in a second formation sequence, or vice versa.

Each S/D region 164 may form either a source or a drain, respectively, of associated FEOL transistors and is connected to respective end surface of the active nanolayers 108 of a nanolayer stack. Similarly, each faux S/D region 165 may be utilized by one or more passive devices such as, resistors, capacitors, inductors, transformers, diodes, within the passive device region.

Each S/D region 164 and each faux S/D region 165 is composed of a semiconductor material and a dopant. As used herein, a “source/drain” region can be a source region or a drain region depending on subsequent wiring and application of voltages during operation of the applicable transistor and a “faux source/drain” region is structurally the same as a “source/drain” region without an associated channel, gate, or the like.

The semiconductor material that provides each of the S/D regions 164 and the faux S/D regions 165 may be composed of one of the semiconductor materials mentioned above for the semiconductor structure. For example, the semiconductor material that provides the S/D region 164 and faux S/D regions 165 can be compositionally the same, or compositionally different from each active nanolayer 108. The dopant that is present in the S/D regions 164 and faux S/D regions 165 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “n-type” refers to the addition of impurities that contributes free electrons to an intrinsic semiconductor. In a silicon containing semiconductor material, examples of n-type dopants, include, but are not limited to, antimony, arsenic and phosphorous. For clarity, different S/D regions 164 may have different shading and may represent different dopant type S/D regions 164

The S/D regions 164 and the faux S/D regions 165 may be epitaxially grown or formed. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, S/D epitaxial growth conditions promote in-situ Boron doped SiGe for p-type transistor and phosphorus or arsenic doped silicon or Si: C for n-type transistors.

In some examples, the epitaxial growth that forms the S/D region 164 and the faux S/D regions 165 occurs or is promoted from the top surface of upper substrate 102, from the upper surface of backside contact placeholders 162 (or separation layer 163 thereupon), or the like, from the end surfaces of the active nanolayers 108, while epitaxial growth may be limited or does not occur from neighboring STI regions 130.

The illustrated semiconductor IC device 100 may be further fabricated by next forming interlayer dielectric (ILD) 176. For example, a blanket ILD 176 may be deposited over the S/D region(s) 164, over the faux S/D regions 165, over the STI region(s) 130, over the sacrificial gate structures, and over the gate spacers 140, and the like.

The ILD 176 can be any suitable material, such as, for example, porous silicates, carbon doped oxides, silicon dioxides, silicon nitrides, silicon oxynitrides, OPL, or other dielectric materials. Any known manner of forming the ILD 176 can be utilized. The ILD 176 can be formed using, for example, CVD, PECVD, ALD, flowable CVD, spin-on dielectrics, or PVD.

The illustrated semiconductor IC device 100 may be further fabricated by next removing the sacrificial gate structures and then forming replacement gate structures 170 in place thereof.

The sacrificial gate structures may be removed by initially removing the sacrificial gate and sacrificial gate oxide by a removal technique, such as one or more series of etches. For example, such removal may be accomplished by a wet chemical etching process in which one or more chemical etchants are used to remove the sacrificial gate and sacrificial gate oxide of the sacrificial gate structures. Next, or simultaneously, the active nanolayers 108 may be released by removing the sacrificial nanolayers within the nanolayer stacks. After the removal of sacrificial nanolayers, void spaces may be formed above and/or below the active nanolayers 108.

The illustrated semiconductor IC device 100 may be further fabricated by next forming a replacement gate structure 170 in place of the removed sacrificial gate structures around the active nanolayers 108, upon STI region(s) 130, upon the bottom isolation 142, etc. Replacement gate structure(s) 170 may be formed by initially forming an interfacial layer on the gate spacers 140, on the active nanolayers 108, on the bottom isolation 142, on the inner spacers 144, etc. that are interior to and/or upon the respective surfaces interior to the opening created by the removal of the sacrificial gate structure and the releasing of the active nanolayers 108. The replacement gate structure(s) 170 may be further formed by forming a high-κ layer to cover the exposed surfaces of the interfacial layer. A high-κ material is a material with a higher dielectric constant than that of SiO₂. The high-κ layer can include a single layer or multiple layers, such as metal layer, liner layer, wetting layer, and adhesion layer. The replacement gate structure(s) 170 may be further formed by depositing a work function (WF) gate upon the high-κ layer. The WF gate can be comprised of a conductor or metal, such as, e.g., copper (Cu), cobalt (Co), aluminum (Al), platinum (Pt), gold (Au), tungsten (W), titanium (Ti), nitride (N³⁻) or any combination thereof. In general, the WF gate sets the threshold voltage (Vt) of the device. The high-κ layer may separate the WF gate from the nanolayer channel (i.e., active nanolayer 108). The replacement gate structure(s) 170 may be further formed by depositing a conductive gate 172. In an example, when none of the previous replacement gate material(s) are utilized in the replacement gate structures, the conductive gate may be formed upon the same or similar surfaces as those upon which the interfacial layer, described above, may be formed. In other examples, when one or more of the interfacial layers, the high-κ layer, the WF gate, or the like, are utilized in the replacement gate structures, the conductive gate may be formed upon the most recent structural formation thereof. The conductive gate 172 can be comprised of a conductor material and/or metal, such as but not limited to, e.g., tungsten, aluminum, ruthenium, rhodium, cobalt, copper, tantalum, titanium, carbon nanowire materials including graphene, or the like.

After the replacement gate structure 170, the top surface of the semiconductor IC device 100 may be planarized by a planarization technique such as a CMP, mechanical grinding process, or the like. After the planarization technique, respective top surfaces of the ILD 176, gate spacers 140, replacement gate structures 170, or the like, may be substantially horizontal and/or may be substantially coplanar.

The illustrated semiconductor IC device 100 may be further fabricated by next forming a frontside contact ILD 176.1. The frontside contact ILD 176.1 may be formed upon respective top surfaces of replacement gate structure(s) 170, ILD 176, and gate spacers 140. The frontside contact ILD 176.1 may be formed by depositing a dielectric material, such as, for example, porous silicates, carbon doped oxides, silicon dioxides, silicon nitrides, silicon oxynitrides, or other dielectric materials.

The illustrated semiconductor IC device 100 may be further fabricated by next forming frontside contacts 180 within the frontside contact ILD 176.1 and the ILD 176. The frontside contacts 180 may be formed by patterning respective frontside contact openings within frontside contact ILD 176.1 and ILD 176, respectively, from the frontside (i.e., from above the semiconductor IC device 100, as depicted, downward to respective structures thereof). The frontside contact 180 may be in direct or indirect physical and electrical contact and/or may physically meld with respective material(s) of one or more regions of the semiconductor IC device 100

The frontside contacts 180 may be formed by initially forming frontside contact opening(s). The frontside contact(s) 180 may be further formed by depositing conductive material such as metal into the respective frontside contact opening(s). In an example, frontside contact(s) 180 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. Subsequently, the respective top surfaces of frontside contact(s) 180 and the frontside contact ILD 176.1 may be substantially horizontal and/or substantially coplanar. In embodiments, the frontside contact(s) 180 are fabricated in middle-of-line (MOL) fabrication operations and may be illustrations of MOL frontside contacts.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., FEOL transistors, the BEOL is made up of interconnects and wiring, and the MOL is an interconnect between the FEOL and BEOL that includes material to prevent the diffusion of BEOL metals to FEOL devices.

BEOL is the second portion of IC fabrication where the individual devices (e.g., transistors, capacitors, resistors, etc.) become interconnected with wiring on the semiconductor IC device, e.g., the metallization layer or layers of a wafer. BEOL includes contacts, insulating layers (dielectrics), metal levels, and bonding sites for chip-to-package connections. In the BEOL, part of the fabrication stage contacts (pads), wires, vias and dielectric structures are formed. For modern IC processes, more than one metal layers may be added in the BEOL. In the present example, there are multiple BEOL levels each on opposites sides of the semiconductor IC device 100. First, a frontside BEOL network 182 is formed on the frontside of the semiconductor device 100. Subsequently, a backside BEOL network 270, as depicted in FIG. 12, is formed.

In the depicted example, the frontside BEOL network 182 is formed over the contact ILD 176.1 and upon the frontside contacts 180. Respective wires within the frontside BEOL network 182 may be electrically connected to the one or more S/D regions 164, to the one or more faux S/D regions 165, to the one or more replacement gate structure(s) 170, or the like, by a respective frontside contact(s) 180. For example, respective wire(s) within the frontside BEOL network 182 may be electrically connected to appropriate S/D regions 164 by a frontside contact 180, another and different group of respective wire(s) within the frontside BEOL network 182 may be electrically connected to appropriate replacement gate structures 170, and another and different group of respective wire(s) within the frontside BEOL network 182 may be electrically connected to appropriate faux S/D regions 165.

The frontside BEOL network 182 is located directly on the frontside surface of the MOL structure (e.g., contact ILD 176.1, frontside contact(s) 180, etc.). The frontside BEOL network 182 can include one or more dielectric material layers (including one of the dielectric materials mentioned above for the frontside ILD 176) and contains metal wires (the metal wires can be composed of any electrically conductive metal or electrically conductive metal alloy) embedded therein. In some embodiments, the frontside metal wires within the frontside BEOL network 182 are composed of Cu. The frontside BEOL network 182 can include “x” numbers of frontside metal levels, wherein “x” is an integer starting from 1. The frontside BEOL network 182 may further contain conductive pads that are connected to one or more of the metal wires and may be used to connect the semiconductor IC device 100 to an external and/or higher-level structure, such as a chip carrier, motherboard, or the like.

The illustrated semiconductor IC device 100 may be further fabricated by next bonding carrier wafer 184 to the frontside BEOL network 182. The carrier wafer 184 can include one of the semiconductor materials mentioned above for the semiconductor structure and the carrier wafer 184 may be attached to the semiconductor IC device 100 by a wafer-to-wafer bonding technique.

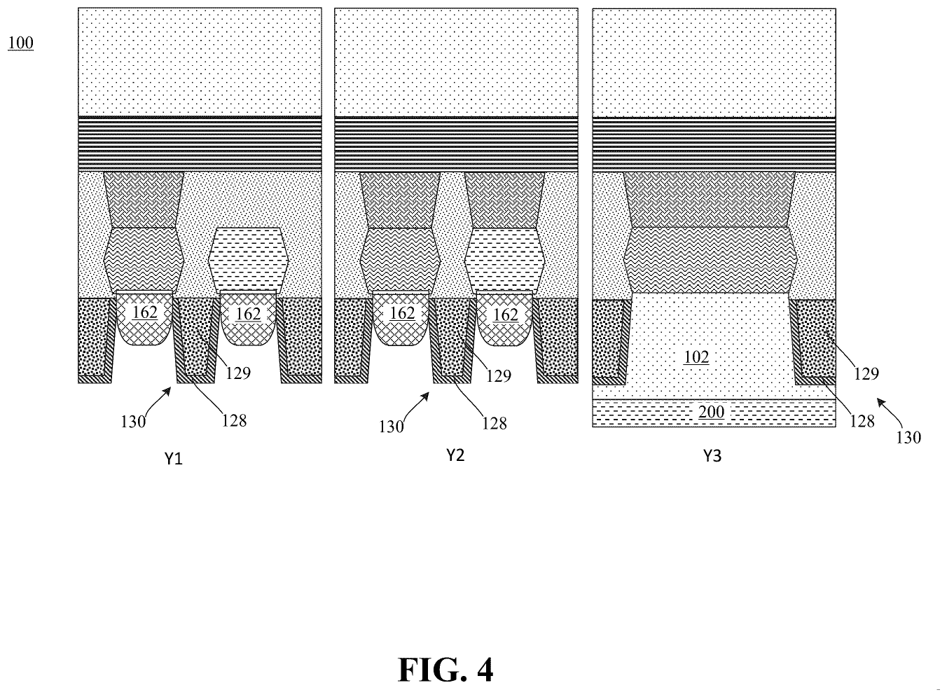

FIG. 4 depicts cross-sectional views of the semiconductor IC device 100 after fabrication operations, in accordance with embodiments of the present disclosure. In the depicted fabrication stages, the substrate structure may be removed in the logic regions and may be maintained and/or partially removed in the passive device region. For example, the lower substrate 101, the etch stop layer 103, and the upper substrate 102 may be removed in the logic regions and the lower substrate 101 and the etch stop layer 103 may be removed in the passive device region.

The substrate structure may be recessed by flipping the semiconductor IC device 100 and removing the lower substrate 101 using any removal technique, such as a combination of wafer grinding, CMP, dry, and/or wet etch. In the example depicted, lower substrate 101 is removed by an etch that utilizes etch stop layer 103 as the etch stop. In this example, removal of lower substrate 101 exposes the bottom surface of etch stop layer 103. The etch stop layer 103 may be removed by a subtractive removal technique such as a CMP, dry and/or wet etch. Upon removal of the etch stop layer 103, the bottom surface upper substrate 102 is exposed. The removal of etch stop layer 103 may be selective to the material of upper substrate 102. For example, etch stop layer 103 is removed by an etch that utilizes upper substrate 102 as the etch stop.

The upper substrate 102 may be removed in the logic regions and may be maintained in the passive device region(s) by lithography and etch process(es). In such process(es), a mask 200 may be applied to the backside of semiconductor IC device 100 and patterned. The mask may be a masking material such as a dielectric (e.g., a nitride), an organic planarization layer (OPL), or the like. The mask 200 may be removed in the logic regions, which may expose the upper substrate 102 while the upper substrate 102 within passive device region(s) is protected and retained. With the logic regions exposed and the passive device region(s) protected, the remaining upper substrate 102 therein may be removed by an appropriate substrative removal technique, such as an etch. The etch may be timed or otherwise controlled to remove the material of substrate 102 selective to the STI regions 130, to the backside contact placeholders 162, to the bottom isolation 142, or the like within the logic regions. As the respective backsides of STI regions 130, backside contact placeholders 162, bottom isolation 142, or the like, may be exposed within the logic regions. Subsequently, the mask 200 may be removed by an etch, OPL ash, or the like, which may again expose the upper substrate 102 within the passive device region.

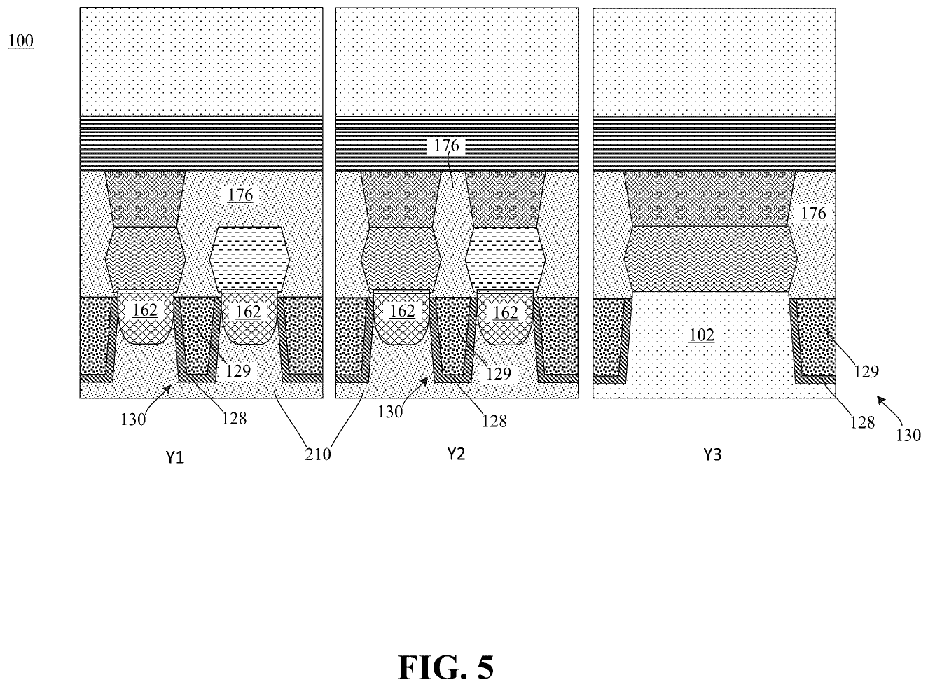

FIG. 5 depicts cross-sectional views of semiconductor IC device 100 shown after illustrative fabrication operation(s), in accordance with one or more embodiments. In the depicted fabrication stage, backside ILD 210 may be formed upon the exposed backside of the semiconductor IC device 100.

The backside ILD 210 may be formed upon the respective exposed surfaces of the STI regions 130, the backside contact placeholder(s) 162, the bottom isolation 142, the upper substrate 102, and the like. The backside ILD 210 may be formed by depositing a dielectric material, such as, for example, porous silicates, carbon doped oxides, silicon dioxides, silicon nitrides, silicon oxynitrides, or other dielectric materials. In an example, the backside ILD 210 and the ILD 176 may be composed of the same material(s). Any appropriate deposition technique for forming the backside ILD 210 can be utilized. In an example, the backside ILD 210 may be formed to a thickness below the respective bottom surfaces of the STI regions 130 and/or below the bottom surface of the upper substrate 102.

Subsequently, a planarization process, such as a CMP process or a mechanical grinding process, may remove excess portions of the backside ILD 210. The planarization process may result in the respective backsides of the backside ILD 210 and the upper substrate 102 being substantially horizontal and/or substantially coplanar.

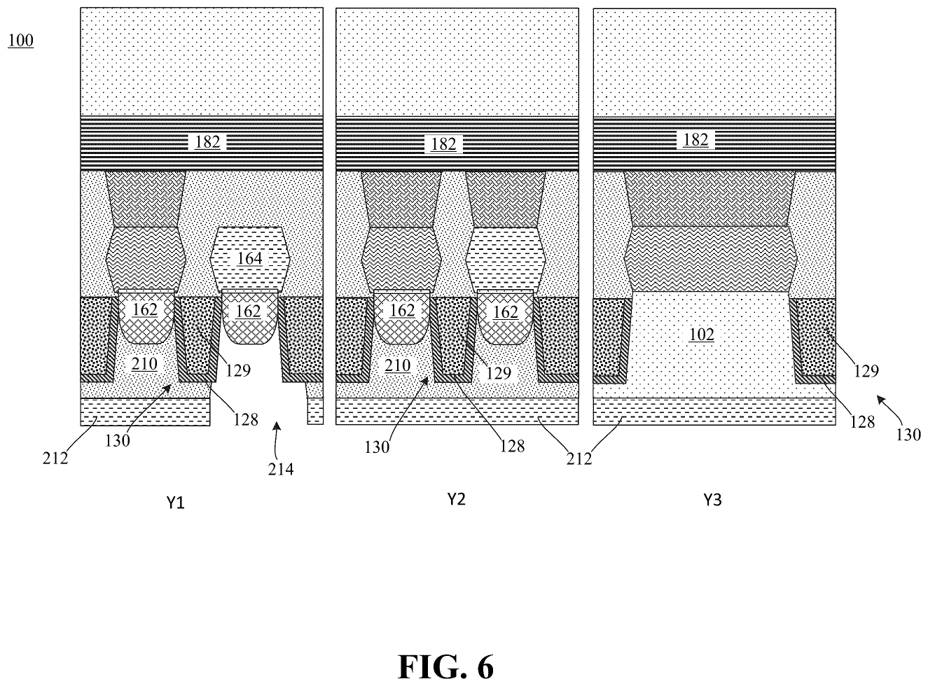

FIG. 6 depicts cross-sectional views of semiconductor IC device 100 shown after illustrative fabrication operation(s), in accordance with one or more embodiments. In the depicted fabrication stage, backside contact opening(s) 214 may be formed. The backside contact opening(s) 214 may be formed by the same or shared lithography and etch process(es), or sequential lithography and etch processes. In such process(es), a mask 212 may be applied to the backside of the semiconductor IC device 100 and patterned. Openings in the patterned mask 212 may sequentially expose the portion(s) of the underlying backside ILD 210. Using the patterned mask 212 an etchant may remove the exposed portions of the ILD 210 and may expose the inline backside contact placeholder 162. The etch may be selective to the respective material(s) of the STI regions 130 and to the backside contact placeholder 162. A respective backside contact opening 214 may be formed to expose the associated inline backside contact placeholder 162 there above (e.g., the backside contact placeholder 162 that is below a S/D region 164 that is not connected to the frontside BEOL network 182).

Subsequently, the backside contact placeholder(s) 162 and associated separation layer 163 (if present) that are exposed by a respective backside contact opening 214 may be removed by a substrative removal technique, such as an etch. In one example, the entire applicable contact placeholder(s) 162 may be removed. Subsequently, associated separation layer(s) 163 may also be removed thereby exposing at least a portion of the S/D region(s) 164 there above. Optionally, the exposed S/D region(s) 164 may be at least partially gouged such that a portion of the expose S/D region 164 is removed by the subtractive removal technique.

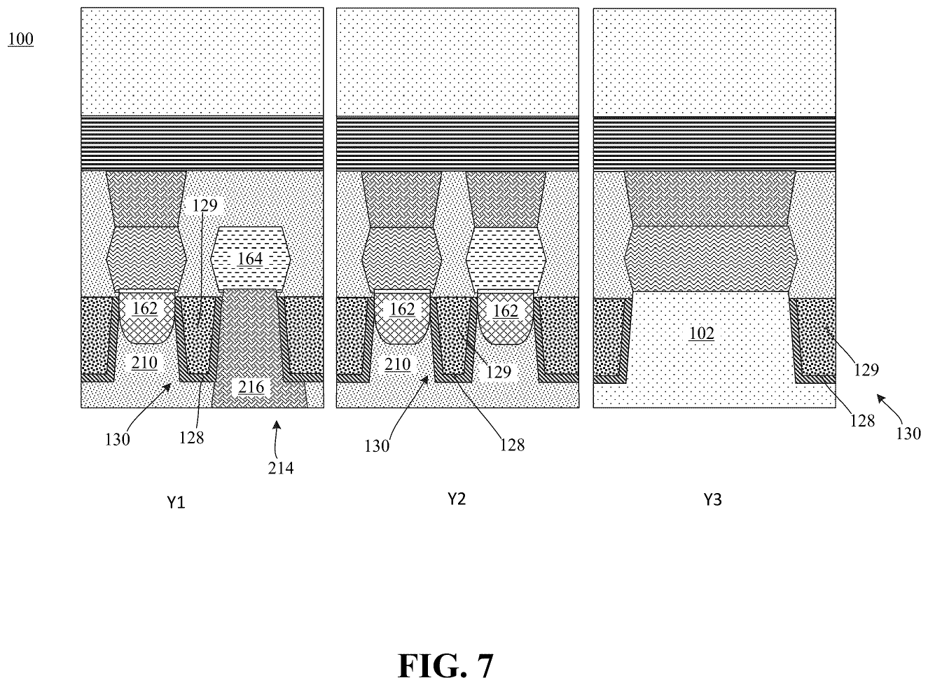

FIG. 7 depicts cross-sectional views of semiconductor IC device 100 shown after illustrative fabrication operation(s), in accordance with one or more embodiments. In the depicted fabrication stage, backside contact(s) 216 may be formed within a respective backside contact opening 214.

Respective backside contacts 216 may be formed within a respective backside contact opening 214 by depositing conductive material, such as metal, into the respective backside contact opening(s) 214. In an example, backside contact(s) 216 may be simultaneously formed by depositing a liner, such as Ni, NiPt or Ti, etc. onto the backside of semiconductor IC device 100 and into the backside contact openings 214, depositing an adhesion liner, such as TiN, TaN, etc. upon the liner, and by depositing a conductive fill, such as Al, Ru, W, Co, Cu, etc. upon the adhesion liner. In the depicted illustration, the backside contact 216 may be formed within the backside contact opening 214 directly against the associated exposed S/D region 164.

Subsequently, a planarization process, such as a CMP, may expose a bottom surface of the backside ILD 210. As a result, the respective backside or bottom surfaces of backside contact(s) 216 and backside ILD 210 may be substantially horizontal and/or substantially coplanar.

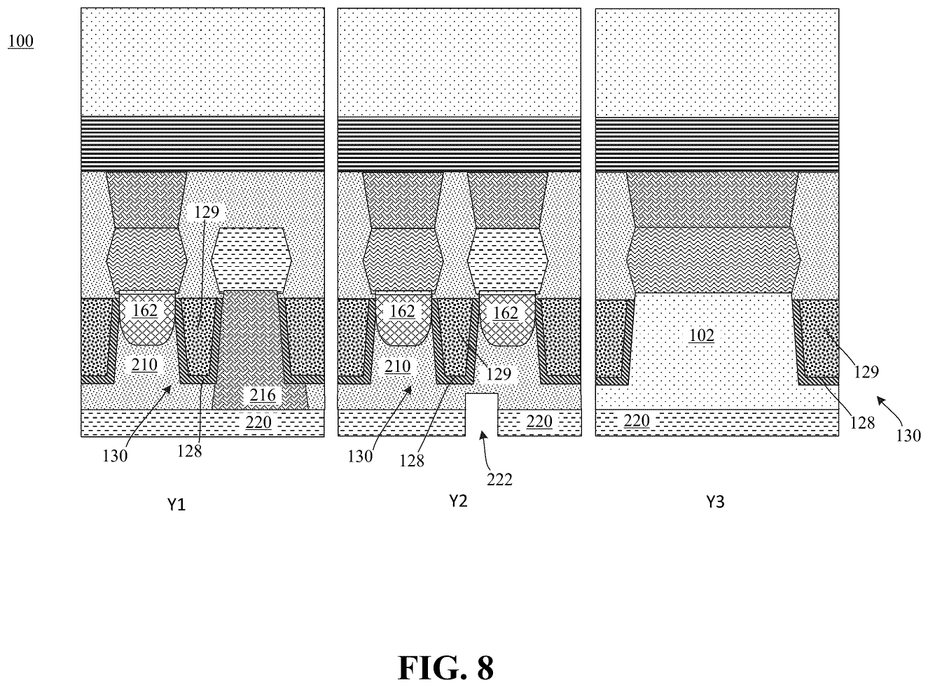

FIG. 8 depicts cross-sectional views of semiconductor IC device 100 shown after illustrative fabrication operation(s), in accordance with one or more embodiments. In the depicted fabrication stage, backside ILD 210 may be patterned by forming one or more backside openings 222 in the backside ILD 210 within the logic region(s).

Backside ILD 210 may be patterned by lithography and etch processes. For example, a mask 220 may be applied to the backside of semiconductor IC device 100 and patterned by lithography and etching techniques. The patterning forms the one or more backside openings 222 within the mask 220. Next, the same or subsequent etch may utilize the mask 220 to remove a portion of the backside ILD 210 that is exposed by the backside opening(s) 222. The etch may be timed or otherwise controlled to remove the backside ILD 210 material to a depth such that a well surface or top surface (as depicted) of the backside opening 222 is below respective bottom surface(s) of the STI regions 130, as depicted. Subsequently, the mask 220 may be removed by an etch, OPL ash, or the like, which may again expose the upper substrate 102 within the passive device region and the backside ILD 210 in the logic regions.

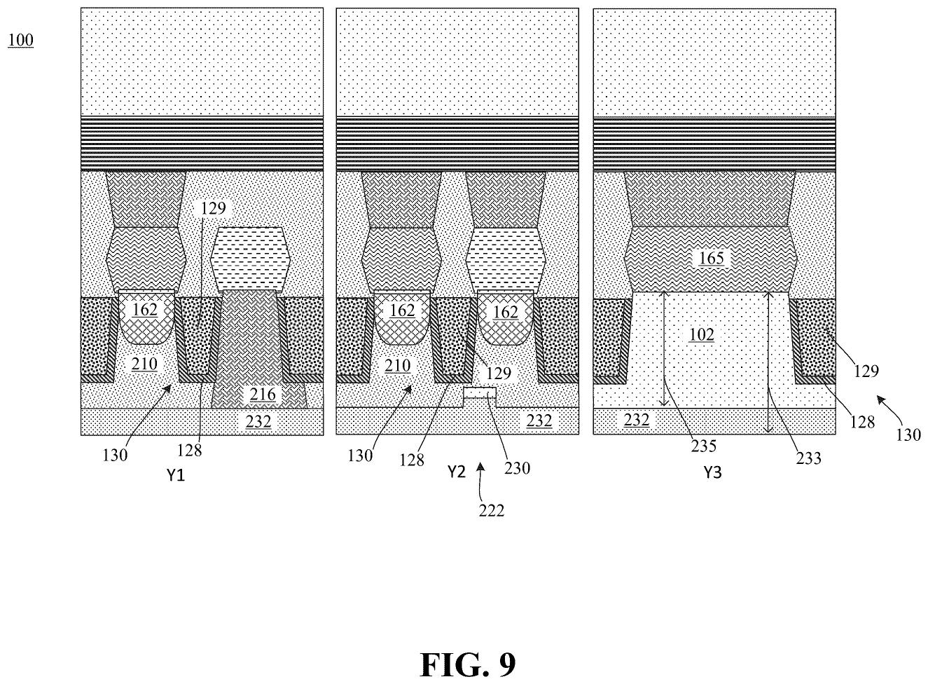

FIG. 9 depicts cross-sectional views of semiconductor IC device 100 shown after illustrative fabrication operation(s), in accordance with one or more embodiments. In the depicted fabrication stage, an amorphous semiconductor layer may be formed on the backside of the semiconductor IC device 100 and laser annealed to form a crystalline semiconductor layer 232.

The amorphous semiconductor layer may be an amorphous silicon layer or other amorphous semiconductor material and may be formed by depositing such material upon the backside ILD 210 and upon the backside contact(s) 216 in the logic region(s) and upon the upper substrate 102 within the passive device region. The amorphous semiconductor layer can be formed using, for example, CVD, PECVD, ALD, flowable CVD, spin-on dielectrics, PVD, or the like.

Laser annealing the amorphous semiconductor layer may adequately crystalize the amorphous semiconductor material layer to resultantly form the crystalline semiconductor layer 232. Laser annealing may limit exposure or subjection other regions of the semiconductor IC device 100 (e.g., S/D regions 164) to temperatures that which causes material property or structure degradation, or the like. In other examples, other localized annealing techniques may be utilized to crystalize the amorphous semiconductor material layer 230 to resultantly form the crystalline semiconductor layer 232. In an example, as depicted, a residual portion of the amorphous semiconductor layer 230 may remain in the backside opening 222 due to the relatively larger thickness between the backside surface of the crystalline semiconductor layer 232 and the backside opening 222 compared to the thickness between the backside surface of the crystalline semiconductor layer 232 and the backside ILD 210.

When the amorphous semiconductor layer is locally annealed, e.g., by a laser, the amorphous semiconductor layer may melt on the surface of the semiconductor IC device 100 and partially melt in the backside opening(s) 222. When cooling, the backside opening(s) 222 allows a single grain to grow from the backside opening(s) 222 into the field, thereby achieving a large crystalline semiconductor layer 232 island in the logic region(s). Therefore, the backside opening(s) 222 may allow or provide for the growth of the crystalline semiconductor layer 232 island within the logic region, where because there is a lack of semiconductor substrate, templating therefrom is not possible as it is in the passive region.

For clarity, with the addition of the crystalline semiconductor layer 232 to the backside of the upper substrate 102 within the passive device region, there is relatively increased semiconductor material below the faux S/D regions 165. For example, a vertical thickness 233 between the backside surface of the faux S/D regions 165 and the backside surface of the crystalline semiconductor layer 232 is greater than a vertical thickness 235 between the backside surface of the faux S/D regions 165 and the backside surface of the upper substrate 102. The relatively increased vertical thickness 233 may improve functionality of one or more passive devices, such as such as resistors, capacitors, inductors, transformers, diodes, within the passive device region.

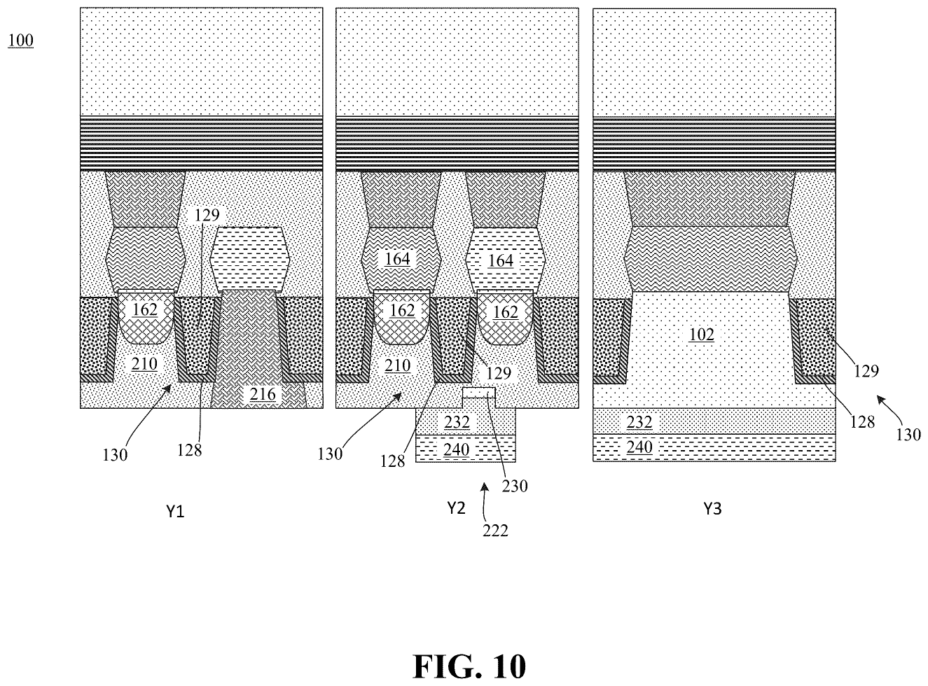

FIG. 10 depicts cross-sectional views of semiconductor IC device 100 shown after illustrative fabrication operation(s), in accordance with one or more embodiments. In the depicted fabrication stage, crystalline semiconductor layer 232 may be patterned within the logic regions to form one or more respective backside transistor channels.

The crystalline semiconductor layer 232 may be patterned by the same or shared lithography and etch process(es), or sequential lithography and etch processes. In such process(es), a mask 240 may be applied to the backside of the crystalline semiconductor layer 232 and patterned. Openings in the patterned mask 240 may sequentially expose the portion(s) of the underlying crystalline semiconductor layer 232. Using the patterned mask 240 an etchant may remove the exposed portions of the crystalline semiconductor layer 232 and may expose the inline backside ILD 210. The etch may be selective to the respective material(s) of the backside ILD 210. The retained crystalline semiconductor layer 232 may form respective backside transistor channels. As depicted, one or more respective backside transistor channels may be integrated with at least the crystalline semiconductor layer 232 within respective backside openings 222. In an example, as depicted, a backside transistor channel may be located under one or more S/D regions 164 of respective and/or adjacent FEOL transistors.

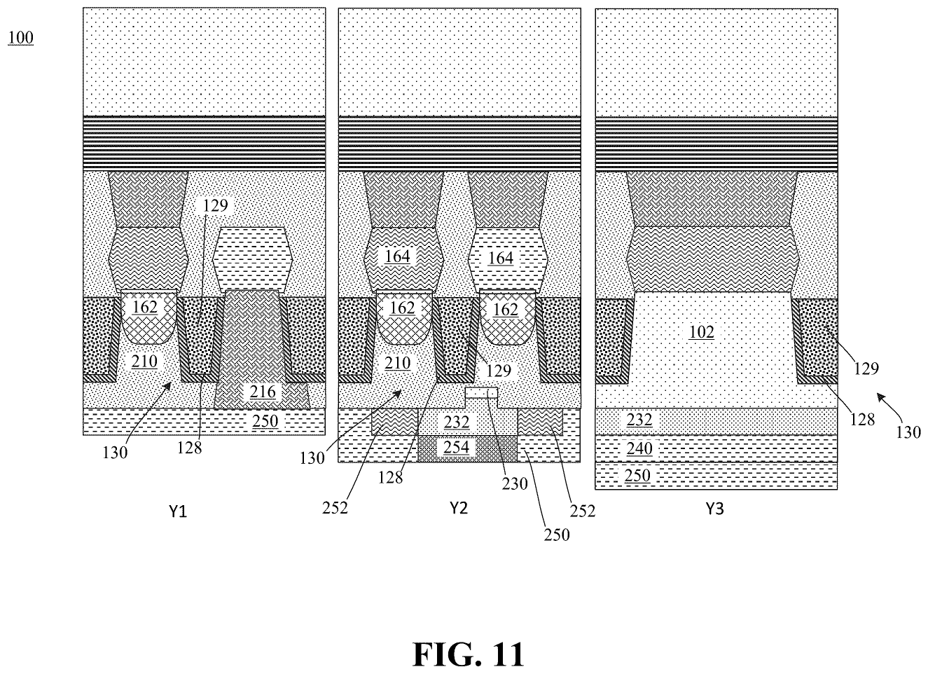

FIG. 11 depicts cross-sectional views of semiconductor IC device 100 shown after illustrative fabrication operation(s), in accordance with one or more embodiments. In the depicted fabrication stage, one or more respective backside transistors may be formed within the logic regions.

The backside transistor(s) may be formed by forming respective backside source/drain regions 252 against respective side surfaces of the associated backside transistor channel. In one example, the backside source/drain regions 252 may be formed by lithography and etching techniques that form a patterned source/drain mask. A doped semiconductor material may be formed within the patterned source/drain mask and form the backside source/drain regions 252. In another example, the backside source/drain regions 252 may be formed by epitaxial growth of a doped semiconductor material from the side surfaces of the backside transistor channel. The epitaxial growth may be timed or otherwise controlled to grow a predetermined or otherwise adequate volume of doped semiconductor material against the side surfaces of the backside transistor channel.

Subsequently, the backside source/drain regions 252 may be locally annealed, for example by laser annealing techniques. Laser annealing may limit exposure or subjection other regions of the semiconductor IC device 100 (e.g., S/D regions 164) to temperatures that which causes material property or structure degradation, or the like.

The backside transistor(s) may be further formed by forming respective backside gates 254 against a backside surface of the associated backside transistor channels. The backside gate(s) 254 may be formed by depositing a gate mask 250 and subsequently patterning the gate mask to form an opening therewithin to expose the backside surface of the associated backside transistor channels. The backside gate(s) 254 may be formed by initially forming an interfacial layer upon the exposed backside surfaces of the associated backside transistor channels that are interior to and/or upon the respective surfaces interior to the opening created by the patterning of gate mask 250.

The backside gate(s) 254 may be further formed by depositing a high-κ layer to cover the interfacial layer. A high-κ material is a material with a higher dielectric constant than that of SiO₂. The high-κ layer can include a single layer or multiple layers, such as metal layer, liner layer, wetting layer, and adhesion layer. The backside gate(s) 254 may be further formed by depositing a work function (WF) gate upon the high-κ layer. The WF gate can be comprised of a conductor or metal. In general, the WF gate sets the threshold voltage (Vt) of the device. Other metals that may be desired to further fine tune the effective work function (eWF) and/or to achieve a desired resistance value associated with current flow through the gate in the direction parallel to the plane of the nanolayer channel.

The backside gate(s) 254 may be further formed by depositing a conductive material upon the WF gate. In an example, when none of the previous replacement gate material(s) are utilized in the replacement gate structures, the conductive gate may be formed upon the same or similar surfaces as those upon which the interfacial layer, described above, may be formed. In other examples, when one or more of the interfacial layer, the high-layer, the WF gate, or the like, are or are not utilized in the backside gate(s) 254, the conductive gate may be formed upon the most recent structural formation thereof.

The conductive material may be a metal, such as but not limited to, e.g., tungsten, aluminum, ruthenium, rhodium, cobalt, copper, tantalum, titanium, carbon nanowire materials including graphene, or the like.

Subsequently, the backside transistor masks (e.g., mask 240, gate mask 250, or the like) may be removed by a substrative removal technique, such as an etch, OPL ash, or the like.

In an example, as depicted, the backside transistor(s) may be planar transistors in which the backside transistor channel (i.e., crystalline semiconductor layer 232) and source/drain regions 252 may lay on the same horizontal plane. For example, the respective backside surfaces of the crystalline semiconductor layer 232 and the source/drain regions 252 may be substantially coplanar and/or substantially horizontal.

FIG. 12 depicts cross-sectional views of semiconductor IC device 100 shown after illustrative fabrication operation(s), in accordance with one or more embodiments. In the depicted fabrication stage, a backside ILD 260, backside contacts 262, and a backside BEOL network 270 may be formed.

The backside ILD 260 may be formed upon the respective exposed surfaces of the backside ILD 210, the backside contact(s) 216, the backside transistor, and the like. The backside ILD 210 may be formed by depositing a dielectric material, such as, for example, porous silicates, carbon doped oxides, silicon dioxides, silicon nitrides, silicon oxynitrides, or other dielectric materials. In an example, the backside ILD 260 and the backside ILD 210 and/or the ILD 176 may be composed of the same material(s). Any appropriate deposition technique for forming the backside ILD 260 can be utilized. In an example, the backside ILD 260 may be formed to a thickness below the respective bottom surface(s) of the backside transistor(s) (e.g., the backside surface of the backside gate(s) 254).

Next, backside contact opening(s) may be formed within the backside ILD 260 by the same or shared lithography and etch process(es), or sequential lithography and etch processes. In such process(es), a mask may be applied to the backside of the backside ILD 260 and patterned. Openings in the patterned mask may sequentially expose the portion(s) of the underlying backside ILD 260. Using the patterned mask an etchant may remove the exposed portions of the ILD 260 and may expose predetermined regions of the semiconductor IC device 100 (e.g., backside contact(s) 216, backside source/drain regions 252, backside gate 254, a respective region of the passive device within the passive device region (not shown), or the like.

Respective backside contacts 262 may be formed within a respective backside contact opening by depositing conductive material, such as metal, into the respective backside contact opening(s). In an example, backside contact(s) 262 may be simultaneously formed by depositing a liner, such as Ni, NiPt or Ti, etc. onto the backside of semiconductor IC device 100 and into the backside contact openings, depositing an adhesion liner, such as TiN, TaN, etc. upon the liner, and by depositing a conductive fill, such as Al, Ru, W, Co, Cu, etc. upon the adhesion liner. In the depicted illustration, a backside contact 262 may be formed within a respective backside contact opening directly against a backside contact 216, a backside source/drain region 252, a backside gate 254, and/or a respective region of the passive device within the passive device region (not shown).

Subsequently, a planarization process, such as a CMP, may expose a bottom surface of the backside ILD 260. As a result, the respective backside or bottom surfaces of backside contact(s) 262 and backside ILD 260 may be substantially horizontal and/or substantially coplanar.

The backside BEOL network 270, such as a backside power distribution network (BSPDN) may be formed upon the backside contact(s) 262 and upon the backside ILD 260. The backside BEOL network 270 may include signal wires for signal routing and power wires for providing power potential (e.g., VDD, VSS, etc.). The backside BEOL network 270 may allow for the distribution of power wires and signal wires between both the frontside and backside of the semiconductor IC device. The backside BEOL network 270 may further allow for the full or partial decoupling of signal routing and/or power routing and/or allows for dividing or splitting power wires and/or signal wires between both the frontside and backside of the semiconductor IC device. By incorporating the backside BEOL network 270, routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

The backside BEOL network 270 may be indirectly electrically and/or indirectly physically connected to the one or more S/D regions 164 by way of a combination of the backside contact 216 and the backside contact 262. Further, the backside BEOL network 270 may be indirectly electrically and/or indirectly physically connected to the backside source/drain region 252 by a respective backside contact 262. Even further, the backside BEOL network 270 may be indirectly electrically and/or indirectly physically connected to the backside gate 254 by a respective backside contact 262.

The backside BEOL network 270 can include one or more dielectric material layers and contains backside conductive wires and/or interconnects, such as VIAs, embedded therein. In some embodiments, the backside wires within the backside BEOL network 270 are composed of Cu. The backside BEOL network 270 can include “x” numbers of backside metal levels, wherein “x” is an integer starting from 1. If not included in frontside BEOL network 182, backside BEOL network 270 may further contain conductive pads that are connected to one or more of the backside metal wires and may be used to connect the semiconductor IC device 100 to the external and/or higher-level structure.

In an example, signal routing and power routing is effectively split between the frontside BEOL network 182 and the backside BEOL network 270. For example, at least 90% of the frontside metal wires (e.g., furthest from the transistors 100.2, 100.4, 100.6, 100.8, and 100.10) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires and the remainder backside metal wires which are usually present in metal levels furthest away from the backside contacts, can be used as signal routing wires. Power routing wires may be less dense than signal routing wires. A signal routing wire is defined herein as a conductive feature, such as a wire, interconnect, or the like, that is configured to electrically carry a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

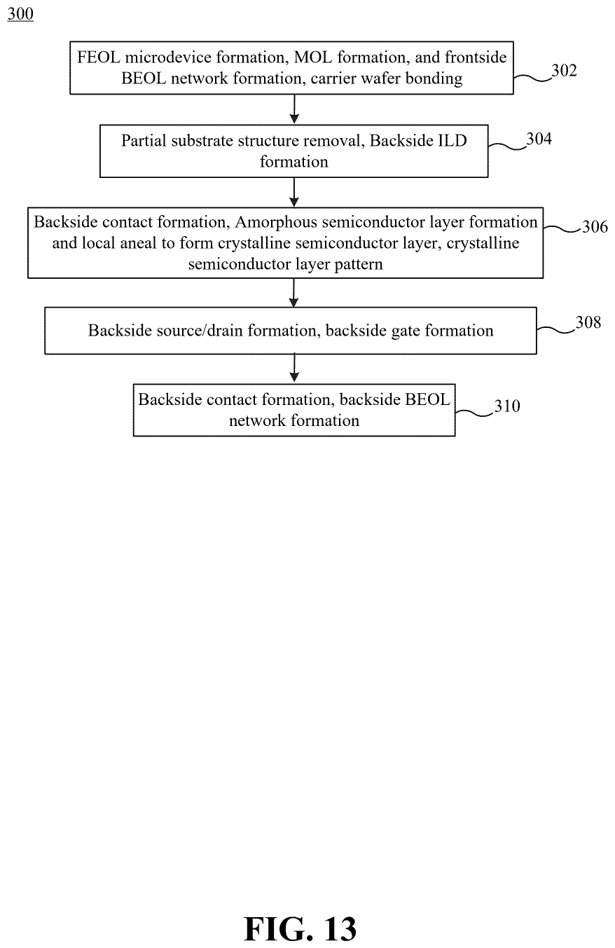

FIG. 13 depicts a flow diagram illustrating a method 300 to fabricate a semiconductor IC device, such as semiconductor IC device 100. The depicted fabrication operations of method 300 are illustratively depicted and described above with reference to one or more of FIG. 3 through FIG. 12 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming one or more front end of line (FEOL) microdevices, such as FEOL transistors, with forming middle of line (MOL) structures, such as frontside contact(s), with forming a frontside back end of line (BEOL) network, and with attaching a carrier wafer thereto. For example, one or more FEOL transistors, such as transistors that utilize source/drain regions 164, active nanolayers 108, and replacement gate structures 170 are formed in logic region(s) of the semiconductor IC device, faux source/drain regions 165 may be formed within a passive device region of the semiconductor IC device in the same or similar fabrication stage as the source/drain regions 164, and one or more frontside contacts 180 are formed that may contact components or regions (such as source/drain regions 164, replacement gate structures 170, faux source/drain regions 165, etc.), and the frontside BEOL network 182 is formed upon the one or more frontside contacts, and a carrier wafer 184 is bonded to the frontside BEOL network 182.

At block 304, the semiconductor IC device may be flipped, and a substrate associated with the FEOL microdevices may be removed while the substrate associated with a passive device region is maintained. For example, the substrate structure within the logic region(s) may be removed and the substrate structure within the passive device region(s) may be maintained. Further, in block 304, a backside ILD is formed at least within the logic region. For example, backside ILD 210 may be formed upon the backside surfaces of the semiconductor IC device 100 that are exposed by the removal of the substrate structure.

At block 306, method 300 may continue by forming first backside contact(s) within the backside ILD in the logic region, with forming an amorphous semiconductor layer, locally annealing the amorphous semiconductor layer to form a crystalline semiconductor layer and patterning the crystalline semiconductor layer in the logic region to form one or more backside channels. For example, first backside contact opening(s) 214 are formed within the backside ILD 210 in the logic region(s) and respective backside contact(s) 216 are formed therewithin. Optionally, one or more backside openings 222 may be formed within the logic regions. Next, amorphous semiconductor layer 230 is formed upon the backside of the semiconductor IC device 100. This amorphous semiconductor layer 230 may be locally annealed (e.g., laser annealed, etc.) to crystalize the amorphous semiconductor layer 230 and form crystalline semiconductor layer 232. A residual portion of the amorphous semiconductor layer 230 may remain in the one or more backside openings 222. Next, the crystalline semiconductor layer 232 may be patterned the logic region(s) to form, for example, one or more backside channels of a backside transistor.

At block 308, method 300 may continue with forming backside source/drain regions and backside gate(s) against respective backside channels. For example, backside source/drain regions 252 may be formed against respective sidewalls and backside gate 254 may be formed against a backside surface of a particular backside channel.

At block 310, method 300 may continue with forming another set of backside contacts and with forming a backside BEOL network. For example, another backside ILD 260 may be deposited over the backside of the semiconductor IC device 100. The backside ILD 260 may adequately electrically isolate the backside source/drain regions 252 from the backside gate 254. Next, another set of backside contact openings may be formed within the backside ILD 260 to expose associated regions of the semiconductor IC device 100. Next, a second set of one or more backside contact(s) 262 are formed within a respective backside contact openings. Next, backside BEOL network 270 over the second set of backside contact(s).

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a passive device region comprising a semiconductor substrate region below a doped semiconductor region and a crystalline semiconductor material layer directly coupled with a backside of the semiconductor substrate region;
a logic region comprising a front end of line (FEOL) transistor with a first source/drain region and a second source/drain region, and a backside contact directly coupled with the first source/drain region; and
wherein a frontside surface of the crystalline semiconductor material layer is substantially coplanar with a backside surface of the backside contact.

2. The semiconductor IC device of claim 1, wherein the logic region further comprises a backside interlayer dielectric around the backside contact.

3. The semiconductor IC device of claim 2, wherein the logic region further comprises a backside transistor comprising a channel composed of a residual portion of the crystalline semiconductor material layer.

4. The semiconductor IC device of claim 3, wherein the residual portion of the crystalline semiconductor material layer comprises an upper section above the backside of the semiconductor substrate region and a lower section below the backside of the semiconductor substrate region.

5. The semiconductor IC device of claim 4, wherein the logic region further comprises an amorphous semiconductor region directly coupled to a frontside surface of the upper section of the residual portion of the crystalline semiconductor material layer.

6. The semiconductor IC device of claim 5, wherein the backside transistor further comprises a first backside source/drain region directly coupled to a first sidewall of the residual portion of the crystalline semiconductor material layer and a second backside source/drain region directly coupled to a second sidewall of the residual portion of the crystalline semiconductor material layer.

7. The semiconductor IC device of claim 6, wherein the backside transistor further comprises a backside gate directly coupled to a backside surface of the residual portion of the crystalline semiconductor material layer.

8. The semiconductor IC device of claim 7, wherein the backside contact, the first backside source/drain region, the second backside source/drain region, and the backside gate are electrically connected to a backside back end of line (BEOL) network.

9. The semiconductor IC device of claim 8, wherein the second source/drain region and the doped semiconductor region are electrically connected to a frontside BEOL network.

10. A semiconductor integrated circuit (IC) device comprising:
a semiconductor substrate;
a doped semiconductor region upon a frontside of the semiconductor substrate;
a crystalline semiconductor material layer upon a backside of the semiconductor substrate;
a front end of line (FEOL) transistor with a first source/drain region and a second source/drain region, and a backside contact directly coupled with the first source/drain region; and
wherein a frontside surface of the crystalline semiconductor material layer is substantially coplanar with a backside surface of the backside contact.

11. The semiconductor IC device of claim 10, further comprising:
a backside interlayer dielectric around the backside contact.

12. The semiconductor IC device of claim 11, further comprising:
a backside transistor comprising a channel that includes a residual portion of the crystalline semiconductor material layer.

13. The semiconductor IC device of claim 12, wherein the residual portion of the crystalline semiconductor material layer comprises an upper section above the backside of the semiconductor substrate and a lower section below the backside of the semiconductor substrate.

14. The semiconductor IC device of claim 13, further comprising:
an amorphous semiconductor region directly coupled to a frontside surface of the upper section of the residual portion of the crystalline semiconductor material layer.

15. The semiconductor IC device of claim 14, wherein the backside transistor further comprises a first backside source/drain region directly coupled to a first sidewall of the residual portion of the crystalline semiconductor material layer and a second backside source/drain region directly coupled to a second sidewall of the residual portion of the crystalline semiconductor material layer.

16. The semiconductor IC device of claim 15, wherein the backside transistor further comprises a backside gate directly coupled to a backside surface of the residual portion of the crystalline semiconductor material layer.

17. The semiconductor IC device of claim 16, further comprising a backside back end of line (BEOL) network and wherein the backside contact, the first backside source/drain region, the second backside source/drain region, and the backside gate are electrically connected to the backside BEOL network.

18. The semiconductor IC device of claim 17, further comprising a frontside BEOL network and wherein the second source/drain region and the doped semiconductor region are electrically connected to the frontside BEOL network.

19. A semiconductor integrated circuit (IC) device fabrication method comprising:
forming a transistor upon a semiconductor substrate;
within a logic region, removing the semiconductor substrate, and within a passive device region, maintaining the semiconductor substrate;
forming a backside contact in direct contact with a source/drain region of the transistor;
forming an amorphous semiconductor material layer upon a backside of the semiconductor IC device; and
laser annealing the amorphous semiconductor material layer to form a crystalline semiconductor material layer.

20. The semiconductor IC device fabrication method of claim 19, further comprising:
maintaining the crystalline semiconductor material layer in the passive device region and patterning the crystalline semiconductor material layer in the logic region.

21. The semiconductor IC device fabrication method of claim 20, wherein the patterning the crystalline semiconductor material layer in the logic region forms a backside transistor channel composed of a residual portion of the crystalline semiconductor material layer.

22. The semiconductor IC device fabrication method of claim 21, further comprising:
forming a first backside source/drain region against a first sidewall of the residual portion of the crystalline semiconductor material layer; and
forming a second backside source/drain region against a second sidewall of the residual portion of the crystalline semiconductor material layer.

23. The semiconductor IC device fabrication method of claim 22, further comprising:
forming a backside gate against a backside surface of the residual portion of the crystalline semiconductor material layer.

24. A semiconductor integrated circuit (IC) device comprising:
a passive device region comprising a semiconductor substrate structure and a crystalline semiconductor material layer upon a backside of the semiconductor substrate structure;
a logic region comprising a first backside interlayer dielectric (ILD), wherein a backside of the first ILD is coplanar with the backside of the semiconductor substrate structure; and
a second backside ILD upon a backside of the first backside ILD and upon the backside of the crystalline semiconductor material layer.

25. A semiconductor integrated circuit (IC) device comprising:
a passive device region comprising a semiconductor substrate structure and a crystalline semiconductor material layer upon a backside of the semiconductor substrate structure; and
a logic region comprising a backside planar transistor comprising a backside transistor channel and backside transistor source/drain regions;
wherein respective backside surfaces of the backside transistor channel and the backside transistor source/drain regions are coplanar with a backside surface of the crystalline semiconductor material layer.
